(19) United States
(12) Patent Application Publication
(10) Pub. No.: US 2011/0155452 A1
(43) Pub. Date: Jun. 30, 2011

(54) DEVICE HOUSING AND METHOD FOR MAKING SAME

(75) Inventors: YUE-PING LIU, Shenzhen City (CN); YOU-LI LIU, Shenzhen City (CN); HSIANG-JUNG SU, Shindian (TW); WEN-TE LAI, Shindian (TW)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/890,734

(22) Filed: Sep. 27, 2010

(30) Foreign Application Priority Data
Dec. 30, 2009 (CN) 200910312565.2

(51) Int. Cl. H05K 7/14; B32B 38/10; B65D 6/40

(52) U.S. Cl. 174/535; 156/242; 220/601

(57) ABSTRACT

A device housing for an electronic device is provided. The device housing includes a substrate and assembling members protruding from the substrate. The substrate includes a fiber member, a metal member embedded within the fiber member, and a transparent resin layer formed on the fiber member. The fiber member defines openings. The assembling members extend through the openings and connect with the metal member. A method for making the present device housing is also provided.

### BACKGROUND

1. Technical Field

The present disclosure relates to device housings for electronic devices and a method for making the device housings.

2. Description of Related Art

Shells for portable electronic devices are usually made of plastic or metal. Although plastic shells can be formed at one time by injection molding they are not very strong and are not very resistant to abrasion. In contrast, metal shells are stronger and have greater abrasion resistance, but they are also heavier and need much more time for processing.

Fiber (such as carbon fiber and glass fiber) is lightweight and strong, and may be preferable over either plastic or metal. However, it is difficult to manufacture a structurally complex housing with fiber.

Therefore, there is room for improvement within the art.

### BRIEF DESCRIPTION OF THE DRAWINGS

Many aspects of the present device housing and method for making the same can be better understood with reference to the drawing. The components in the drawing are not necessarily drawn to scale, the emphasis instead being placed upon clearly illustrating the principles of the present device housing and method for making the same.

FIG. 1 is an assembled view of the present device housing according to an exemplary embodiment.

FIG. 2 is a schematic cross-section view of the device housing show in FIG. 1 taken along line II-II.

FIG. 3 is a schematic cross-section view of the device housing show in FIG. 1 taken along line III-III.

FIG. 4 is a schematic view of a metal member of the present device housing.

FIG. 5 is a sectional view showing one of the manufacturing processes in the method of manufacturing the device housing according to an exemplary embodiment.

FIG. 6 is a sectional view showing another manufacturing process in the method of manufacturing the device housing according to an exemplary embodiment.

### DETAILED DESCRIPTION

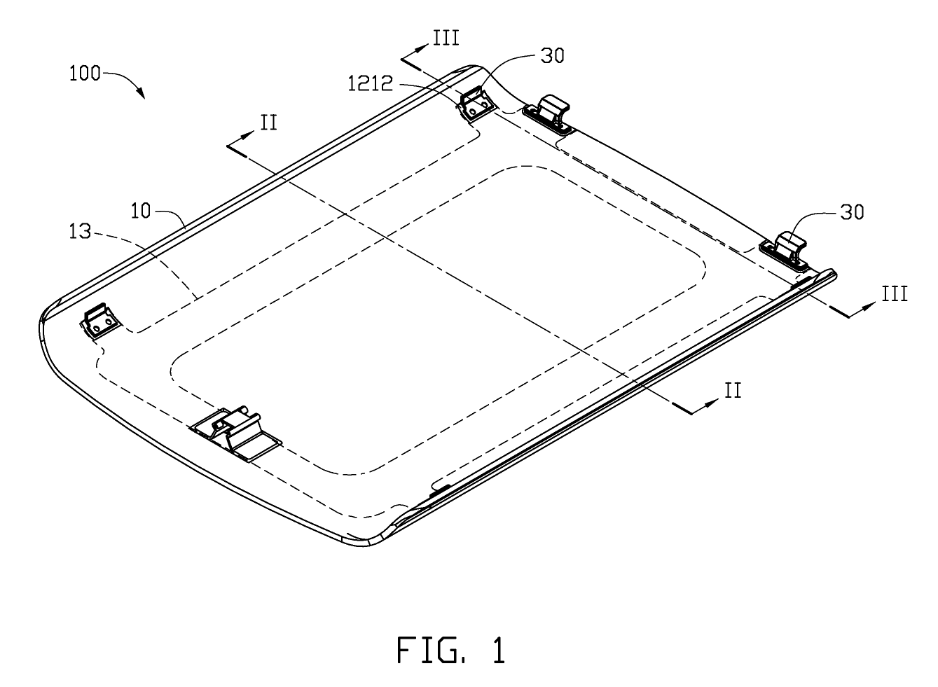

FIG. 1 shows an exemplary device housing 100 for electronic devices (such as mobile phones). In this exemplary embodiment, the device housing 100 may be a cover of a mobile phone. The device housing 100 includes a substrate 10 and assembling members 30 protruding from the substrate 10.

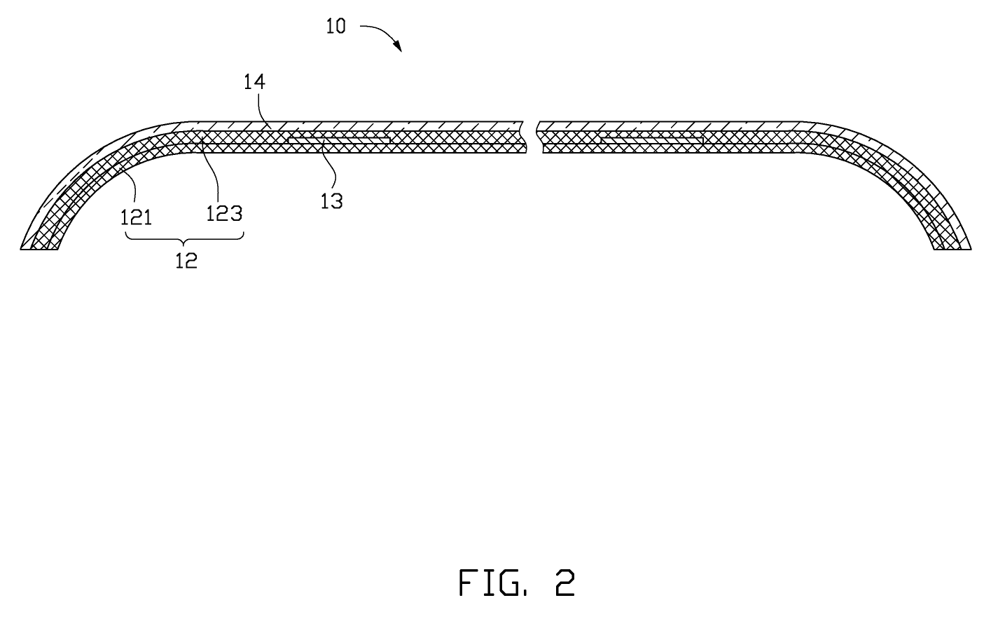

Referring to FIG. 2, the substrate 10 includes a fiber member 12, a metal member 13 embedded within the fiber member 12, and a transparent resin layer 14 formed on the fiber member 12.

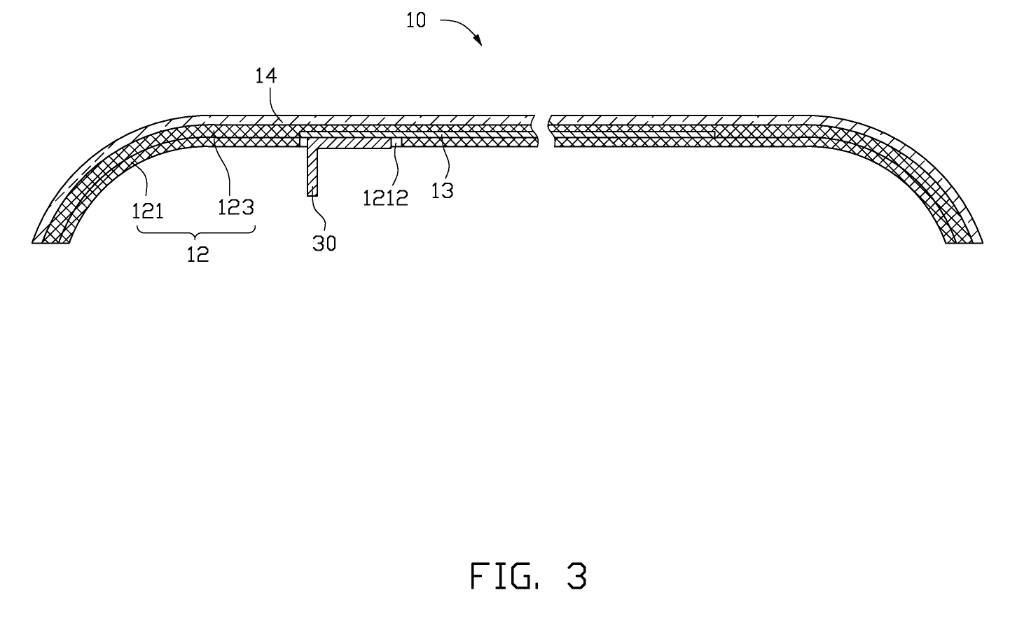

Referring to FIG. 3, the fiber member 12 includes a first woven sheet 121 bonded to a second woven sheet 123. The first woven sheet 121 defines openings 1212. The first woven sheet 121 and the second woven sheet 123 may be composed of hardened fiber cloth impregnated with resin. The fiber cloth may be made of fiber selected from one or more materials of the group consisting of carbon fiber, glass fiber, Kevlar fiber, and hybrid fiber. In this exemplary embodiment, carbon fiber or glass fiber is selected. The resin can be thermosetting resin or thermoplastic resin. The first woven sheet 121 and the second woven sheet 123 may respectively have a thickness of about 0.2 mm to about 0.3 mm. The first woven sheet 121 and the second woven sheet 123 may have any textures.

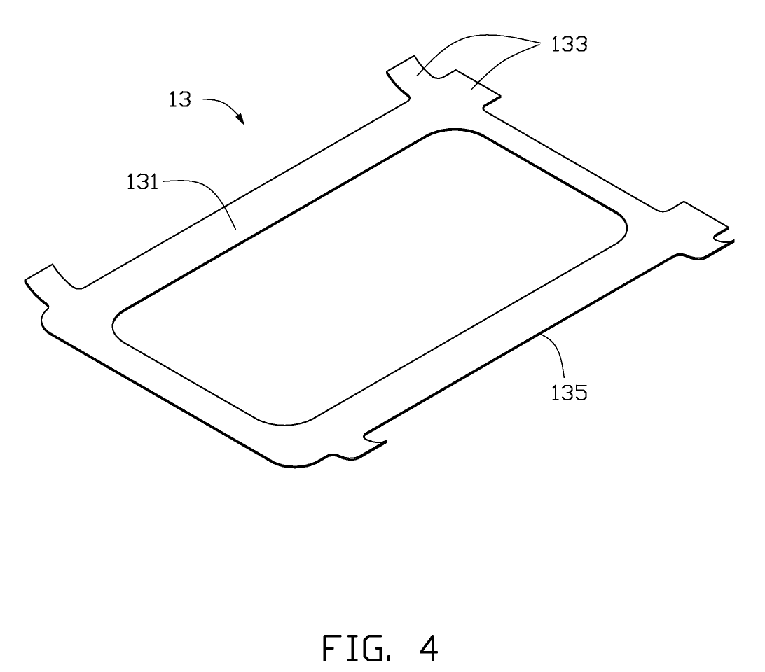

Referring to FIG. 4, the metal member 13 is embedded between the first woven sheet 121 and the second woven sheet 123. In this exemplary embodiment, the metal member 13 has a main body 131 and extending portions 133 connected to the main body 131. The extending portions 133 extend from the peripheral edge 135 of the main body 131. The metal member 13 may be made of one of the group consisting of stainless steel, copper, titanium alloy, and aluminum alloy. In this exemplary embodiment, the metal member 13 is made of stainless steel and has a thickness of about 0.2 mm.

Referring to FIG. 3, the resin layer 14 bonds to the second woven sheet 123. The resin layer 14 is made of transparent resin and has a thickness of about 0.9 mm to about 1.0 mm. The resin layer 14 forms an exterior surface of the device housing 100 and may protect the fiber member 10 from abrasion or damage.

Referring to FIGS. 1 and 3, the assembling members 30 extend through the corresponding openings 1212 and connect with the corresponding extending portions 133. The assembling members 30 may be made of metal, such as stainless steel, copper, titanium alloy, or aluminum alloy. In this exemplary embodiment, the assembling members 30 are made of stainless steel. The assembling members 30 may be connectors such as hooks or clasps configured for assembling the device housing 100 to an electronic device.

An exemplary method for making the device housing 100 may include the following steps.

The metal member 13 and the assembling members 30 are provided. The metal member 13 and the assembling members 30 may be manufactured by, for example, stamping.

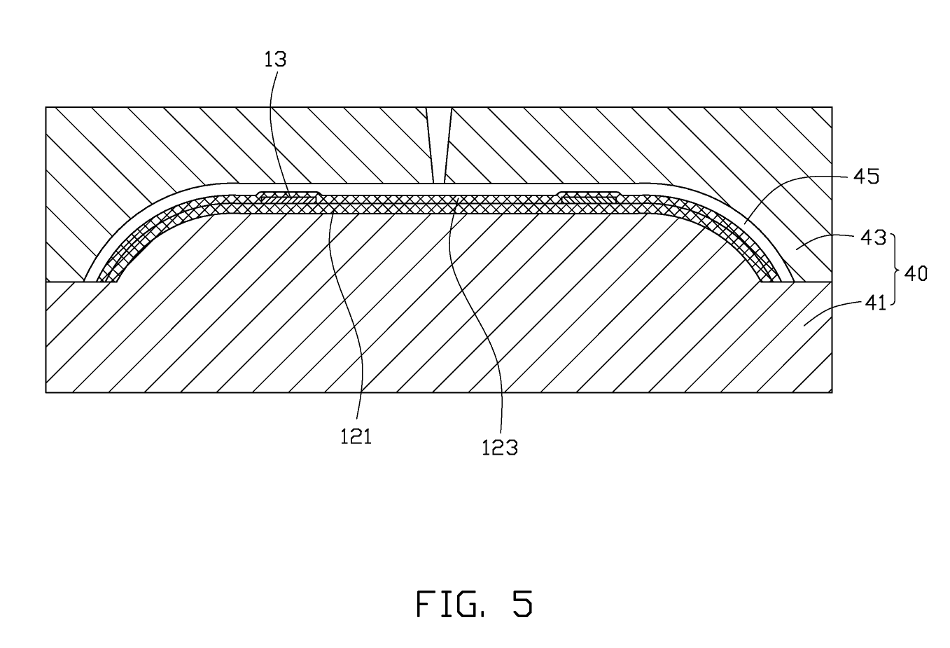

Referring to FIG. 5, a mold 40 having a female mold 41 and a male mold 43 is provided. The male mold 43 engages with the female mold 41 to form a cavity 45.

The first woven sheet 121 and the second woven sheet 123 are formed by cutting an un-hardened fiber cloth impregnated with resin. The fiber cloth may be made of fiber selected from the group consisting of carbon fiber, glass fiber, Kevlar fiber, and hybrid fiber.

The first woven sheet 121, the metal member 13, and the second woven sheet 123 are placed in the mold 40 in sequence, and the metal member 13 is embedded between the first woven sheet 121 and the second woven sheet 123.

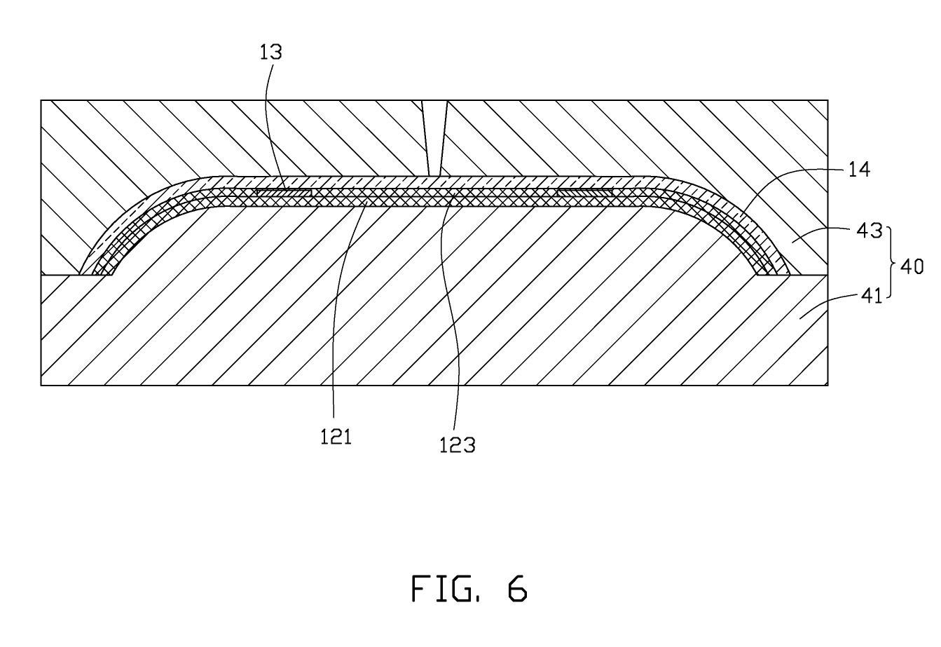

Referring to FIG. 6, molten transparent resin is injected into the closed mold 40 at an injection temperature of about 180-200° C. and with an injection pressure of about 1000 kgf (kilogram force). The resin fills the cavity 45 and forms the resin layer 14 which bonds with the second woven sheet 123. After cooling, the resin layer 14, the first woven sheet 121, the second woven sheet 123, and the metal member 13 are now integrated and form the substrate 10 of the device housing 100.

The first woven sheet 121 may be partially removed by, for example, laser etching, to form the openings 1212, and the extending portions 133 are exposed out of the openings 1212.

The assembling members 30 may be welded to the corresponding extending portions 133. A carbon dioxide (CO₂) laser may be used to perform the welding.

The fiber member 12 can be more than two stacked woven sheets.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A device housing, comprising:
a substrate, the substrate including a fiber member, a metal member embedded within the fiber member, and a transparent resin layer formed on the fiber member, the fiber member defining openings; and
assembling members, the assembling members extending through the openings and connecting with the metal member.

2. The device housing as claimed in claim 1, wherein the assembling members are made of metal.

3. The device housing as claimed in claim 1, wherein the assembling members are for assembling the device housing to an electronic device.

4. The device housing as claimed in claim 3, wherein each assembling member is in a form of hook or clasp.

5. The device housing as claimed in claim 1, wherein the fiber member includes a first woven sheet bonded to a second woven sheet, the metal member embedded between the first woven sheet and the second woven sheet.

6. The device housing as claimed in claim 5, wherein the first woven sheet and the second woven sheet are composed of hardened fiber cloth impregnated with resin.

7. The device housing as claimed in claim 6, wherein the fiber cloth is made of fiber selected from one or more materials of the group consisting of carbon fiber, glass fiber, Kevlar fiber, and hybrid fiber.

8. The device housing as claimed in claim 5, wherein the metal member includes a main body and extending portions connected to the peripheral edge of the main body, the openings are defined through the first woven sheet and arranged to correspond with the extending portions, the assembling members extend through the openings and connect with the extending portions.

9. The device housing as claimed in claim 8, wherein the resin layer bonds to the second woven sheet.

10. The device housing as claimed in claim 1, wherein the metal member is made of stainless steel and has a thickness of about 0.2 mm.

11. The device housing as claimed in claim 1, wherein the resin layer has a thickness of about 0.9 mm to about 1.0 mm.

12. A method for making a device housing, comprising:
providing a metal member and assembling members;
providing a mold;
forming a first woven sheet and a second woven sheet by cutting a fiber cloth impregnated with resin;
placing the first woven sheet, the second woven sheet, and the metal member in the mold in sequence, with the metal member embedded between the first woven sheet and the second woven sheet;
injecting molten resin into the mold to form a transparent resin layer bonding to the second woven sheet, after cooling, the resin layer, the first woven sheet, the second woven sheet, and the metal member being integrated;
removing parts of the first woven sheet to form openings, the metal member partially exposed out of the openings; and
welding the assembling members to the metal member through the openings.

13. The method as claimed in claim 12, wherein the metal member and the assembling members are formed by stamping.

14. The method as claimed in claim 12, wherein the fiber cloth is made of fiber selected from one or more of the group consisting of carbon fiber, glass fiber, Kevlar fiber, and hybrid fiber.

15. The method as claimed in claim 12, wherein the parts of the first woven sheet are removed by laser etching.

16. The method as claimed in claim 12, wherein the injecting step is carried out at an injection temperature of about 180-200° C. and with an injection pressure of about 1000 kgf.

17. The method as claimed in claim 12, wherein the metal member includes a main body and extending portions connected to the peripheral edge of the main body.

18. The method as claimed in claim 12, wherein the assembling members are made of metal.
